(19) United States
(12) Patent Application Publication
(10) Pub. No.: US 2026/0298994 A1
(43) Pub. Date: Oct. 1, 2026

(54) DIGITAL SENSOR FOR DETECTING ELECTROMAGNETIC FAULT INJECTION

(71) Applicant: MEDIATEK INC., Hsinchu City (TW)

(72) Inventors: Ming-Chiang Ting, Hsinchu City (TW); Kuan-Chung Chen, Hsinchu City (TW); Po-Han Chu, Hsinchu City (TW)

(73) Assignee: MEDIATEK INC., Hsinchu City (TW)

(21) Appl. No.: 19/095,070

(22) Filed: Mar. 31, 2025

(51) Int. Cl. G01R 31/00; H03K 5/00; H03K 5/135

(52) U.S. Cl. CPC G01R 31/002; H03K 5/135; H03K 2005/00013

(57) ABSTRACT

The present invention provides a digital sensor including a first delay circuit, a second delay circuit and a sampling circuit. The first delay circuit is configured to delay a clock signal to generate a first clock signal. The second delay circuit is configured to delay the clock signal to generate a second clock signal. The sampling circuit is configured to sample the first clock signal according to the second clock signal to generate a first fault detection result.

### BACKGROUND

Electromagnetic fault injection (EMFI) is a technique used by attackers to manipulate the behavior of integrated circuits (ICs), such as microcontrollers or processors, by generating an intense and sudden variation of magnetic field to chip, wherein this magnetic flow will be captured by some of the metallic loops formed by power and ground networks. EMFI can introduce glitches into the clock signal, which is responsible for synchronizing all operations within a chip. A glitch can shift the clock's timing, causing operations to happen earlier or later than expected. This can result in data being processed before it is stable or after it has been altered, leading to incorrect behavior or errors. In addition, injecting electromagnetic into the power lines can cause random fluctuations (jitter) in the clock signal. This jitter can make the timing of sequential operations unpredictable, affecting the chip's ability to perform tasks correctly, particularly in high-speed circuits that rely on precise timing.

### SUMMARY

It is therefore an objective of the present invention to provide a digital sensor, which can accurately detect if the timing of clock signals is influenced by EMFI, to solve the above-mentioned problems.

According to one embodiment of the present invention, a digital sensor comprising a first delay circuit, a second delay circuit and a sampling circuit is disclosed. The first delay circuit is configured to delay a clock signal to generate a first clock signal. The second delay circuit is configured to delay the clock signal to generate a second clock signal. The sampling circuit is configured to sample the first clock signal according to the second clock signal to generate a first fault detection result.

According to one embodiment of the present invention, a chip comprising a plurality of digital sensors is disclosed. Each of the plurality of digital sensors comprises a first delay circuit, a second delay circuit and a sampling circuit is disclosed. The first delay circuit is configured to delay a clock signal to generate a first clock signal. The second delay circuit is configured to delay the clock signal to generate a second clock signal. The sampling circuit is configured to sample the first clock signal according to the second clock signal to generate a first fault detection result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a digital sensor according to one embodiment of the present invention.

FIG. 2 is a timing diagram of clock signal, first clock signal, second clock signal, third clock signal and fourth clock signal according to one embodiment of the present invention.

FIG. 3 is a schematic diagram showing fault detection results generated by digital sensor under different conditions.

FIG. 4 is a diagram illustrating a chip comprising a protected target circuitry and a plurality of digital sensors according to one embodiment of the present invention.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. The terms “couple” and “couples” are intended to mean either an indirect or a direct electrical connection. Thus, if a first device couples to a second device, that connection may be through a direct electrical connection, or through an indirect electrical connection via other devices and connections.

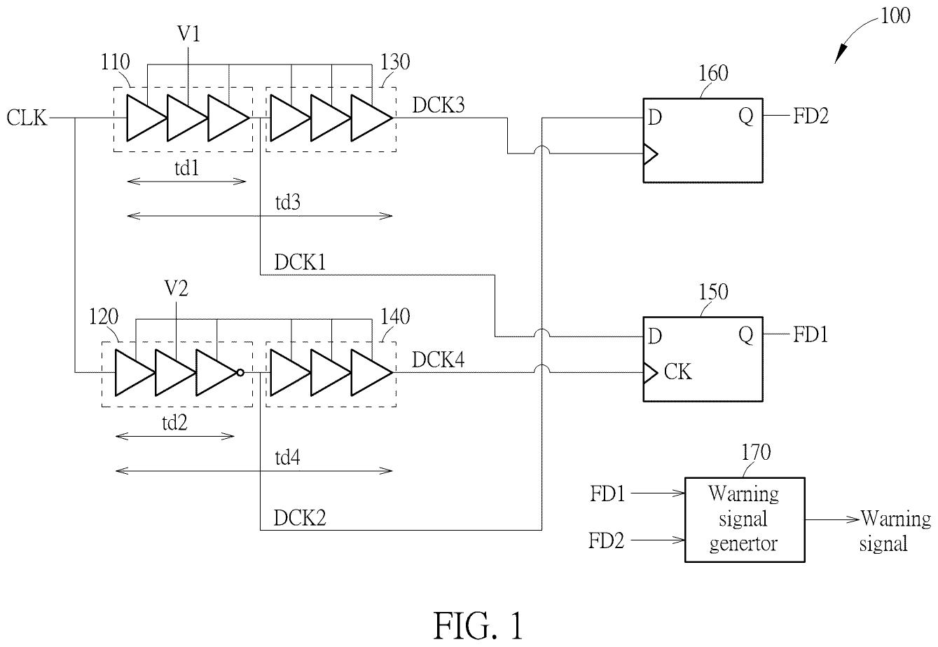

FIG. 1 is a diagram illustrating a digital sensor 100 according to one embodiment of the present invention. As shown in FIG. 1, the digital sensor comprises a first delay circuit 110, a second delay circuit 120, a third delay circuit 130, a fourth delay circuit 140, two sampling circuits 150, 160, and a warning signal generator 170. In this embodiment, each of the first delay circuit 110, the second delay circuit 120, the third delay circuit 130 and the fourth delay circuit 140 comprises one or more delay elements, such as buffers and/or inverters, connected in series. In addition, not a limitation of the present invention, the sampling circuits 150 and 160 can be implemented by D-type flip-flops.

The first delay circuit 110 and the third delay circuit 130 are connected in series, and all the delay elements within the first delay circuit 110 and the third delay circuit 130 are supplied by a first supply voltage V1. The second delay circuit 120 and the fourth delay circuit 140 are connected in series, and all the delay elements within the second delay circuit 120 and the fourth delay circuit 140 are supplied by a second supply voltage V2. In this embodiment, the first supply voltage V1 and the second supply voltage V2 belong to the same power domain, but the first supply voltage V1 and the second supply voltage V2 are from different locations of a chip. That is, ideally the first supply voltage V1 and the second supply voltage V2 have the same voltage level (i.e., no EMI is injected); and there is a certain distance between the locations in the chip used to obtain the first supply voltage V1 and the second supply voltage V2, so that only one of the first supply voltage V1 and the second supply voltage V2 will be significantly affected during a local EMFI.

In the operation of the digital sensor 100, the first delay circuit 110 delays a clock signal CLK to generate a first clock signal DCK1, and the third delay circuit 130 delays the first clock signal DCK1 to generate a third clock signal DCK3. The second delay circuit 120 delays the clock signal CLK to generate a second clock signal DCK2, and the fourth delay circuit 140 delays the second clock signal DCK2 to generate a fourth clock signal DCK4. Then, the sampling circuit 150 uses the fourth clock signal DCK4 to sample the first clock signal DCK1 to generate a first fault detection result FD1, and the sampling circuit 160 uses the third clock signal DCK3 to sample the second clock signal DCK2 to generate a second fault detection result FD2. In addition, the waning signal generator 170 generates a warning signal according to the first fault detection result FD1 and the second fault detection result FD2. The warning signal is used to indicate if one of the first supply voltage V1 and the second supply voltage V2 is influenced by the EMFI.

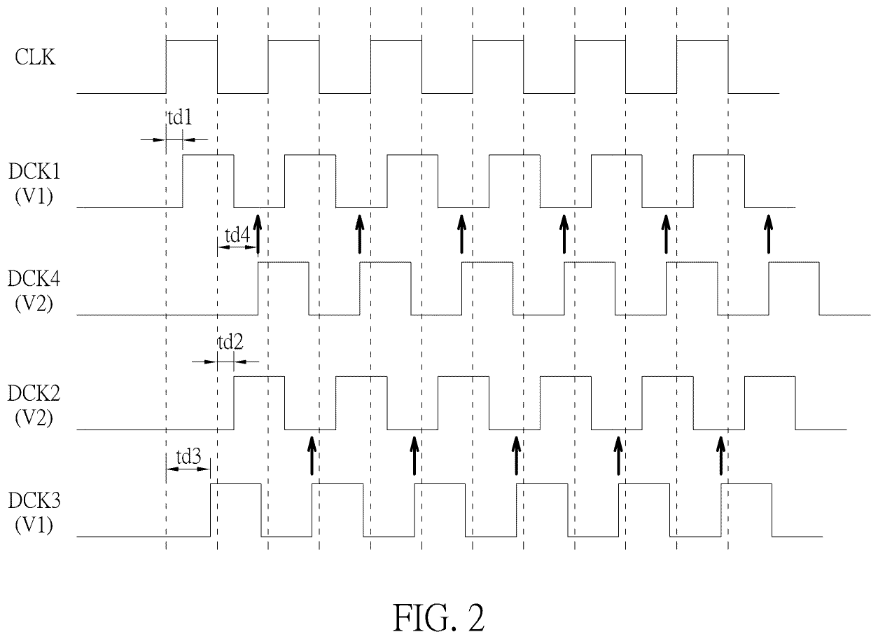

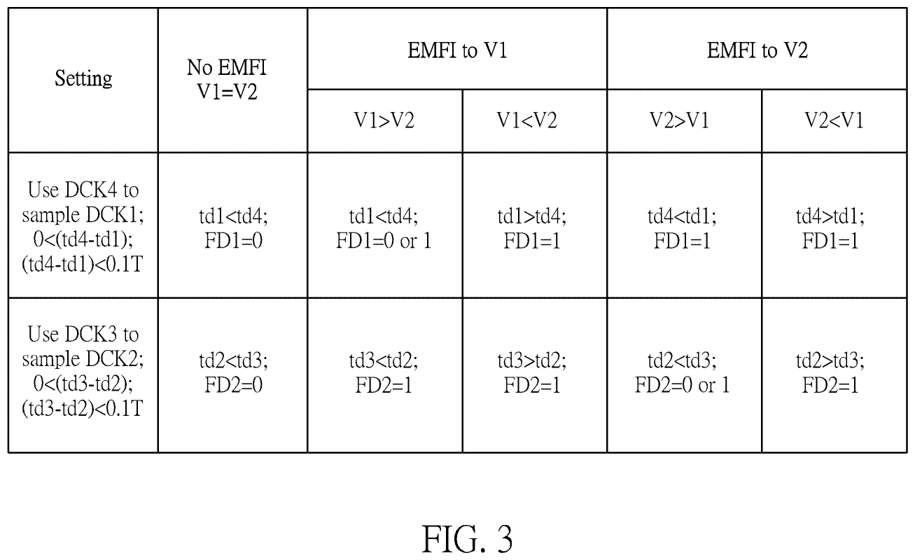

FIG. 2 is a timing diagram of the clock signal CLK, the first clock signal DCK1, the second clock signal DCK2, the third clock signal DCK3 and the fourth clock signal DCK4 according to one embodiment of the present invention. In the embodiment shown in FIG. 2, it is assumed that delay amount td1 of the first delay circuit 110 is similar to delay amount td2 of the second delay circuit 120 having an inverter, that is, the first clock signal DCK1 and the second clock signal DCK2 have nearly inverting phases; and delay amount td3 of the third delay circuit 130 is similar to delay amount td4 of the fourth delay circuit 140 having an inverter, that is, the third clock signal DCK3 and the fourth clock signal DCK4 have nearly inverting phases; and a different “td4−td1” is between zero and 0.1*T, and a difference “td3−td2” is between zero and 0.1*T, wherein “T” is a period of the clock signal CLK. Referring to FIG. 1 to FIG. 3 together, in a normal case and no EMFI is applied to the chip, delay amount td1 of the first delay circuit 110 is smaller than delay amount td4 of the fourth delay circuit 140, and delay amount td2 of the second delay circuit 120 is smaller than delay amount td3 of the third delay circuit 130, so that both the first fault detection result FD1 and the second fault detection result FD2 have a logical value “0”.

When the first supply voltage V1 suffers EMFI, the first supply voltage V1 may be affected and either rise above or fall below the second supply voltage V1. If the first supply voltage V1 becomes greater than the second supply voltage V2, the delay amount td1 of the first delay circuit 110 will still be shorter than the delay amount td4 of the fourth delay circuit 140, so the first fault detection result FD1 outputted by the sampling circuit 150 can be logical value “0” or “1”. In addition, the delay amount td3 of the third delay circuit 130 will become shorter than the delay amount td2 of the second delay circuit 140 due the higher first supply voltage V1, so that the second fault detection result FD2 will become logical value “1”.

If the first supply voltage V1 suffers EMFI, and the first supply voltage V1 becomes lower than the second supply voltage V2, the delay amount td1 of the first delay circuit 110 will become greater than the delay amount td4 of the fourth delay circuit 140, so that the first fault detection result FD1 outputted by the sampling circuit 150 becomes logical value “1”. In addition, the delay amount td3 of the third delay circuit 130 will become more greater than the delay amount td2 of the second delay circuit 120 due the lower first supply voltage V1, so that the second fault detection result FD2 will become logical value “1”.

When the second supply voltage V2 suffers EMFI, the second supply voltage V2 may be affected and either rise above or fall below the first supply voltage V1. If the second supply voltage V2 becomes greater than the first supply voltage V1, the delay amount td4 of the fourth delay circuit 140 will become shorter than the delay amount td1 of the first delay circuit 110, so the first fault detection result FD1 outputted by the sampling circuit 150 becomes logical value “1”. In addition, the delay amount td2 of the second delay circuit 120 still be shorter than the delay amount td3 of the third delay circuit 130, so that the second fault detection result FD2 can be logical value “1” or “0”.

If the second supply voltage V2 suffers EMFI, and the second supply voltage V2 becomes lower than the first supply voltage V1, the delay amount td4 of the fourth delay circuit 140 will become more greater than the delay amount td1 of the first delay circuit 110, so that the first fault detection result FD1 outputted by the sampling circuit 150 becomes logical value “1”. In addition, the delay amount td2 of the second delay circuit 120 will become greater than the delay amount td3 of the third delay circuit 130 due the lower second supply voltage V2, so that the second fault detection result FD2 will become logical value “1”.

In the above embodiment, when the first fault detection result FD1 or the second fault detection result has logical value “1”, it indicates that the first supply voltage V1 or the second supply voltage V2 suffers EMFI. Therefore, the warning signal generator 170 can generates a warning signal to notify the following device to implement some safety mechanisms if one of the first fault detection result FD1 or the second fault detection result has logical value “1”.

In the above embodiment, the digital detector 100 generates two fault detection results FD1 and FD2 to accurately generate a warning signal. However, in other embodiments, the digital detector 100 may generate only one fault detection result to generate a warning signal with slightly lower accuracy. Specifically, the fourth delay circuit 140 and the sampling circuit 150 can be removed from the digital detector 100 shown in FIG. 1, and the sampling circuit 160 can use a clock signal generated according to the first clock signal DCK1 (e.g., DCK1 or DCK3) to sample the second clock signal DCK2 to generate the second fault detection result FD2, and the second fault detection result FD2 serves as the waning signal. In another embodiment, the third delay circuit 130 and the sampling circuit 160 can be removed from the digital detector 100, and the sampling circuit 150 can use a clock signal generated according to the second clock signal DCK2 (e.g., DCK2 or DCK4) to sample the first clock signal DCK1 to generate the first fault detection result FD1, and the first fault detection result FD1 serves as the waning signal.

It is noted that the setting of the delay amount td1, td2, td3 and td4 shown in FIG. 2 are for illustrative, not a limitation of the present invention. In other embodiments, the delay amount td1, td2, td3 and td4 may have different relationship, and the first fault detection result FD1 or the second fault detection result FD2 may have logical value “0” for suffering EMFI. These alternative designs shall fall within the scope of the present invention.

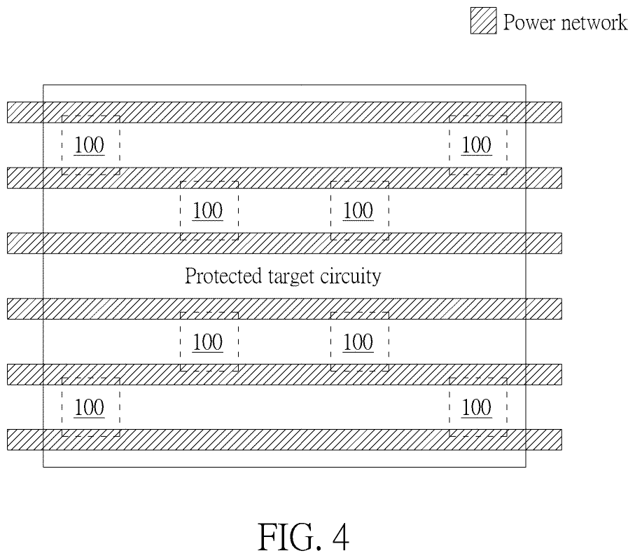

FIG. 4 is a diagram illustrating a chip comprising a protected target circuitry and a plurality of digital sensors 100 according to one embodiment of the present invention. As shown in FIG. 4, a plurality of power network belonging to the same power domain are arranged for the protected target circuitry, and each of the digital sensors 100 receives two supply voltages from different locations of the power network. In this embodiment, the digital sensors 100 can be divided into a plurality groups, and a state machine within the chip can determine if one or more groups suffer EMFI according to the warning signals generated by the digital sensors 100 within the group. For example, the left four digital sensors 100 can be grouped, and the state machine can receive the warning signals outputted by the four digital sensors 100 to determine if the left region of the protected target circuitry suffers the EMFI (e.g., the EMFI is determined if two or more warning signals have the logical value “1”).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A digital sensor, comprising:
a first delay circuit, configured to delay a clock signal to generate a first clock signal;
a second delay circuit, configured to delay the clock signal to generate a second clock signal; and
a first sampling circuit, configured to sample the first clock signal according to the second clock signal to generate a first fault detection result.

2. The digital sensor of claim 1, wherein the first delay circuit is supplied by a first supply voltage, and the second delay circuit is supplied by a second supply voltage, wherein the first supply voltage and the second supply voltage belong to a same power domain, and come from different locations of a chip.

3. The digital sensor of claim 1, further comprising:
a third delay circuit, configured to delay the first clock signal to generate a third clock signal;
a fourth clock signal, configured to delay the second clock signal to generate a fourth clock signal; and
a second sampling circuit, configured to use the third clock signal to sample the second clock signal to generate a second fault detection result;
wherein the first sampling circuit is configured to use the fourth clock signal to sample the first clock signal to generate the first fault detection result.

4. The digital sensor of claim 3, wherein the first delay circuit and the third delay circuit are supplied by a first supply voltage, and the second delay circuit and the fourth delay circuit are supplied by a second supply voltage, wherein the first supply voltage and the second supply voltage belong to a same power domain, and come from different locations of a chip.

5. The digital sensor of claim 3, wherein the first clock signal and the second clock signal have inverting phases.

6. The digital sensor of claim 3, wherein delay amount of the first delay circuit is less than delay amount of the fourth delay circuit, and delay amount of the second delay circuit is less than delay amount of the third delay circuit.

7. The digital sensor of claim 3, further comprising:
a warning signal generator, configured to generate a warning signal to notify a following device if one of the first fault detection result and the second fault detection result indicates that the digital sensor suffers electromagnetic fault injection.

8. A chip, comprising:
a plurality of digital sensors, wherein each of the plurality of digital sensors comprises:
a first delay circuit, configured to delay a clock signal to generate a first clock signal;
a second delay circuit, configured to delay the clock signal to generate a second clock signal; and
a first sampling circuit, configured to sample the first clock signal according to the second clock signal to generate a first fault detection result.

9. The chip of claim 8, wherein the first delay circuit is supplied by a first supply voltage, and the second delay circuit is supplied by a second supply voltage, wherein the first supply voltage and the second supply voltage belong to a same power domain, and come from different locations of the chip.

10. The chip of claim 8, wherein the digital sensor further comprises:
a third delay circuit, configured to delay the first clock signal to generate a third clock signal;
a fourth clock signal, configured to delay the second clock signal to generate a fourth clock signal; and
a second sampling circuit, configured to use the third clock signal to sample the second clock signal to generate a second fault detection result;
wherein the first sampling circuit is configured to use the fourth clock signal to sample the first clock signal to generate the first fault detection result.

11. The chip of claim 10, wherein the first delay circuit and the third delay circuit are supplied by a first supply voltage, and the second delay circuit and the fourth delay circuit are supplied by a second supply voltage, wherein the first supply voltage and the second supply voltage belong to a same power domain, and come from different locations of a chip.

12. The chip of claim 10, wherein the first clock signal and the second clock signal have inverting phases.

13. The chip of claim 10, wherein delay amount of the first delay circuit is less than delay amount of the fourth delay circuit, and delay amount of the second delay circuit is less than delay amount of the third delay circuit.

14. The chip of claim 10, wherein the digital sensor further comprises:
a warning signal generator, configured to generate a warning signal indicating that if the digital sensor suffers electromagnetic fault injection;
wherein the warning signals respectively generated by the plurality of digital sensors are used to determine if a region comprising the plurality of digital sensors suffers electromagnetic fault injection.
